(19) United States
(12) Patent Application Publication
(10) Pub. No.: US 2019/0067199 A1
(43) Pub. Date: Feb. 28, 2019

(54) WIRING BOARD AND ELECTRONIC DEVICE

(71) Applicant: SHINKO ELECTRIC INDUSTRIES CO., LTD., Nagano-shi (JP)

(72) Inventors: Daisuke Takizawa, Nagano-shi (JP); Sachiko Oda, Nagano-shi (JP)

(21) Appl. No.: 16/106,606

(22) Filed: Aug. 21, 2018

(30) Foreign Application Priority Data
Aug. 22, 2017 (JP) 2017-159721

(51) Int. Cl. H01L 23/538; H05K 3/40; H01L 25/10; H01L 23/14; H01L 23/00

(52) U.S. Cl. CPC H01L 23/5384; H01L 23/5389; H05K 3/4007; H01L 25/105; H01L 23/142; H05K 2203/0338; H01L 2224/16227; H01L 2225/1023; H05K 2201/0367; H05K 2201/10674; H01L 24/12

(57) ABSTRACT

A wiring board includes: a connection pad; an insulating layer that covers the connection pad and has an opening portion exposing a portion of the connection pad; and a metal pin that is disposed on the insulating layer and that is connected to the connection pad through a metal bonding material provided in the opening portion. The opening portion includes a main opening portion, and a plurality of protrusive opening portions that communicate with the main opening portion and that protrude outward from an outer circumference of the main opening portion. An outer circumference of a lower end surface of the metal pin, which is opposed to the insulating layer, is located outside the outer circumference of the main opening portion.

This application claims priority from Japanese Patent Application No. 2017-159721 filed on Aug. 22, 2017, the entire contents of which are herein incorporated by reference.

### BACKGROUND

### 1. Technical Field

Embodiments of the present disclosure generally relate to a wiring board and an electronic device.

### 2. Background Art

In the background art, there are stacked type semiconductor devices in each of which an upper-side semiconductor package is stacked on a lower-side semiconductor package. In such a stacked type semiconductor device, the lower-side semiconductor package and the upper-side semiconductor package are connected to each other through metal posts or solder balls (see e.g., JP-A-2015-146384).

As will be described in an undermentioned preliminary matter, in a stacked type electronic device, each connection pad of an upper-side wiring board is connected to each metal pin provided on a lower-side wiring board. The metal pin of the lower-side wiring board is connected to the connection pad exposed from an opening portion of a solder resist layer by a solder.

When the metal pin is displaced on this occasion, an outer circumference of the metal pin is disposed to fall into the opening portion of the solder resist layer. Accordingly, the metal pin is connected to the connection pad with an inclination.

For this reason, it is difficult to reliably connect the connection pad of the upper-side wiring board to the metal pin of the lower-side wiring board to thereby lower a manufacturing yield.

### SUMMARY

Certain embodiments provide a wiring board. The wiring board comprises: a connection pad; an insulating layer that covers the connection pad and has an opening portion exposing a portion of the connection pad; and a metal pin that is disposed on the insulating layer and that is connected to the connection pad through a metal bonding material provided in the opening portion. The opening portion comprises a main opening portion, and a plurality of protrusive opening portions that communicate with the main opening portion and that protrude outward from an outer circumference of the main opening portion. An outer circumference of a lower end surface of the metal pin, which is opposed to the insulating layer, is located outside the outer circumference of the main opening portion.

Certain embodiments provide an electronic device. The electronic device comprises: a first wiring board; and a second wiring board that is electrically connected to the first wiring board. The first wiring board comprises: a first connection pad; an insulating layer that covers the first connection pad, and has an opening portion exposing a portion of the first connection pad; and a metal pin that is disposed on the insulating layer and that is connected to the first connection pad through a metal bonding material provided in the opening portion. The opening portion comprises a main opening portion, and a plurality of protrusive opening portions that communicate with the main opening portion and that protrude outward from an outer circumference of the main opening portion. An outer circumference of a lower end surface of the metal pin, which is opposed to the insulating layer, is located outside the outer circumference of the main opening portion. The second wiring substrate comprises a second connection pad that is connected to an upper end surface of the metal pin, which is opposite to the lower end surface.

### BRIEF DESCRIPTION OF DRAWINGS

FIGS. 1A and 1B are a sectional view and a plan view showing a state in which a metal pin is connected to a connection pad of a lower-side wiring board according to a preliminary matter;

FIG. 2 is a sectional view showing a state in which the metal pin of FIG. 1A is displaced and connected with an inclination;

FIG. 3 is a sectional view showing a state in which a connection pad of an upper-side wiring board is connected to the metal pin of the lower-side wiring board of FIG. 2;

FIGS. 4A and 4B are a plan view and a sectional view showing a state of an opening portion of a solder resist layer that is disposed on a connection pad of a wiring board according to an embodiment;

FIGS. 5A and 5B are a plan view and a sectional view showing a state in which a metal pin is disposed in alignment with the opening portion of the solder resist layer of the wiring board of FIGS. 4A and 4B;

FIGS. 6A and 6B are a plan view and a sectional view showing a state in which the metal pin is disposed in misalignment with the opening portion of the solder resist layer of the wiring board of FIGS. 4A and 4B;

FIGS. 7A and 7B are a plan view and a sectional view showing a state in which the metal pin is disposed in misalignment with the opening portion of the solder resist layer of the wiring board of FIGS. 4A and 4B;

FIGS. 8A and 8B are a plan view and a sectional view showing a state in which the metal pin is disposed in misalignment with the opening portion of the solder resist layer of the wiring board of FIGS. 4A and 4B;

FIGS. 9A and 9B are a plan view and a sectional view showing a first modification of the opening portion of the solder resist layer of the wiring board according to the embodiment;

FIGS. 10A and 10B are a plan view and a sectional view showing a second modification of the opening portion of the solder resist layer of the wiling board according to the embodiment:

FIGS. 11A to 11D are sectional views showing a method for manufacturing the wiring board according to the embodiment;

FIGS. 12A and 12B are sectional views showing a method for manufacturing an electronic device according to the embodiment (Part 1);

FIGS. 13A and 13B are sectional views showing the method for manufacturing the electronic device according to the embodiment (Part 2);

FIG. 14 is a sectional view showing the method for manufacturing the electronic device according to the embodiment (part 3);

FIG. 15 is a sectional view showing the method for manufacturing the electronic device according to the embodiment (part 4);

FIG. 16 is a sectional view showing the method for manufacturing the electronic device according to the embodiment (Part 5);

FIG. 17 is a sectional view showing the method for manufacturing the electronic device according to the embodiment (Part 6);

FIG. 18 is a sectional view showing the method for manufacturing the electronic device according to the embodiment (Part 7);

FIG. 19 is a sectional view showing the method for manufacturing the electronic device according to the embodiment (Part 8);

FIG. 20 is a sectional view showing the method for manufacturing the electronic device according to the embodiment (part 9); and

FIG. 21 is a sectional view showing the electronic device according to the embodiment.

### DETAILED DESCRIPTION

An embodiment will be described below with reference to the accompanying drawings.

A preliminary matter underlying the embodiment will be described prior to description of the embodiment. Description of the preliminary matter is about the details of personal study of the present inventor, and contain techniques not belonging to known techniques.

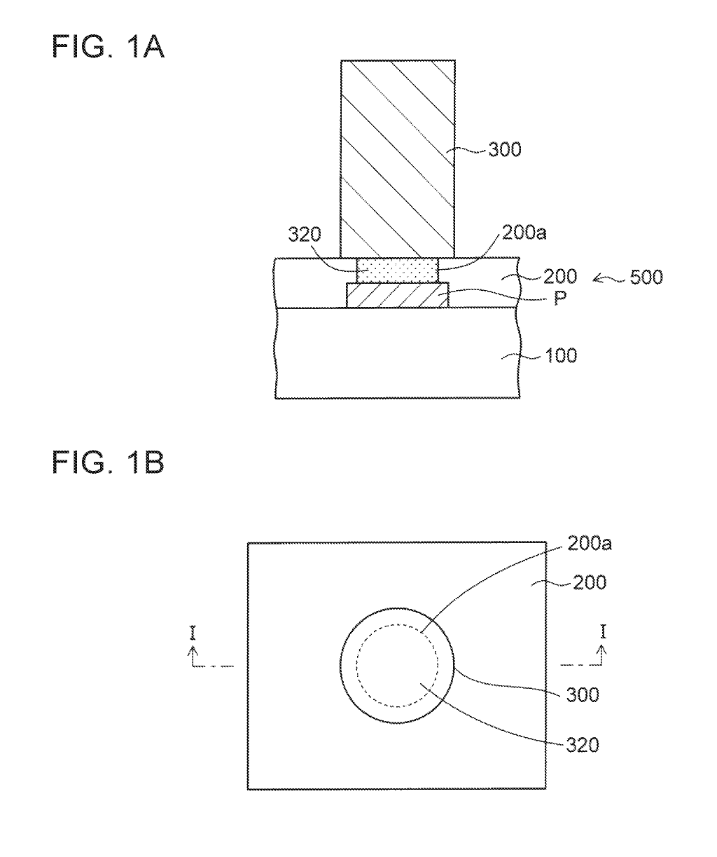

FIGS. 1A and 1B partially show a structure around a metal pin connected to a connection pad of a lower-side wiring board according to the preliminary matter. FIG. 1A is a sectional view taken along a line I-I of FIG. 1B.

As shown in FIG. 1A, connection pads P are formed on an insulating layer 100 in the lower-side wiring board 500. The connection pads P are connected to an internal multilayer wiring layer (not shown) through via conductors (not shown) formed in the insulating layer 100.

A solder resist layer 200 that includes opening portions 200a disposed on the connection pads P is formed on the insulating layer 100. Lower end surfaces of metal pins 300 each of which is shaped like a circular column are connected to the connection pads P through solders 320.

As shown in FIGS. 1A and 1B, a diameter of each of the opening portions 200a of the solder resist layer 200 is set to be smaller than a diameter of each of the metal pins 300.

When the metal pin 300 is disposed in alignment with the opening portion 200a of the solder resist layer 200, an outer circumference of the lower end surface of the metal pin 300 as a whole is disposed in abutment with an upper surface of the solder resist layer 200 surrounding the opening portion 200a. Therefore, the metal pin 300 is connected to the connection pad P through the solder 320 without any inclination.

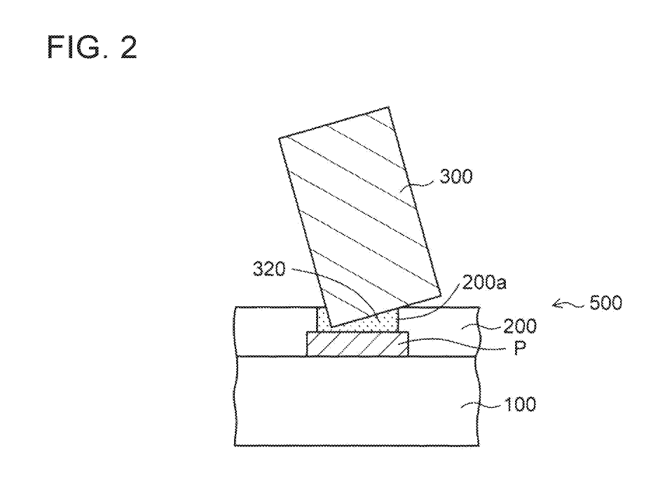

FIG. 2 shows a state in which the metal pin 300 of the lower-side wiring board 500 according to the preliminary matter is disposed in misalignment with the opening portion 200a of the solder resist layer 200.

When the metal pin 300 is disposed to be displaced rightward from an inner wall of the opening portion 200a of the solder resist layer 200, as shown in FIG. 2, a left-side portion of the outer circumference of the lower end surface of the metal pin 300 is disposed to fall into the opening portion 200a of the solder resist layer 200.

Therefore, the metal pin 300 is connected to the connection pad P through the solder 320 in the state in which the metal pin 300 leans leftward due to a step of the solder resist layer 200.

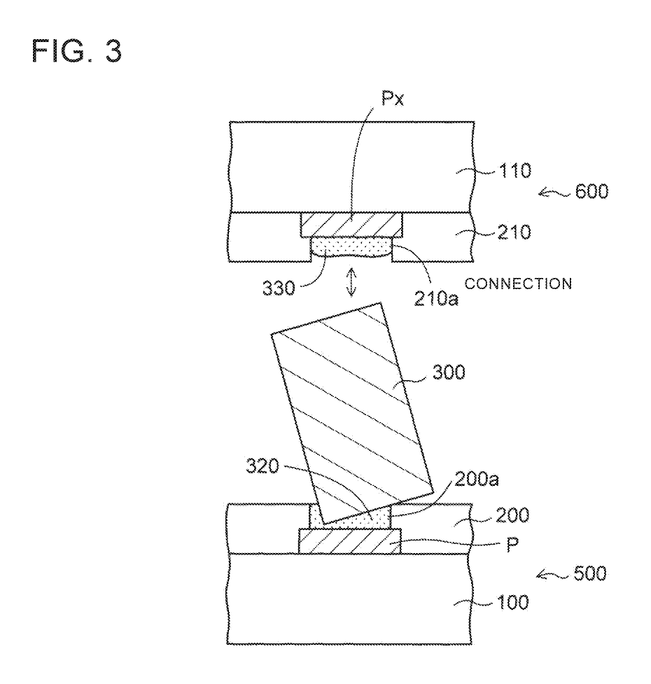

Successively, an upper-side wiring board 600 is prepared, as shown in FIG. 3. The upper-side wiring board 600 is connected to the metal pins 300 of the lower-side wiring board 500 of FIG. 2. Thus, a stacked type electronic device is manufactured. In the upper-side wiring board 600 of FIG. 3, a structure around a connection pad Px is partially shown.

In the upper-side wiring board 600, connection pads Px are formed on an insulating layer 110 (on the bottom of the insulating layer 110 in FIG. 3). In addition, a solder resist layer 210 that includes opening portions 210a disposed on the connection pads Px is formed on the insulating layer 110. Further, solders 330 are applied to the inside of the opening portions 210a of the solder resist layer 210.

The connection pads Px of the upper-side wiring board 600 are connected to upper end surfaces of the metal pins 300 of the lower-side wiring board 500 through the solders 330.

When any of the metal pins 300 of the lower-side wiring board 500 is disposed with an inclination on this occasion, the metal pin 300 is displaced from the corresponding connection pad Px of the upper-side wiring board 600 or does not reach the corresponding connection pad Px.

For this reason, it is difficult to reliably connect the connection pad Px of the upper-side wiring board 600 to the metal pin 300 of the lower-side wiring board 500 to thereby lower a manufacturing yield of the electronic device.

### Embodiment

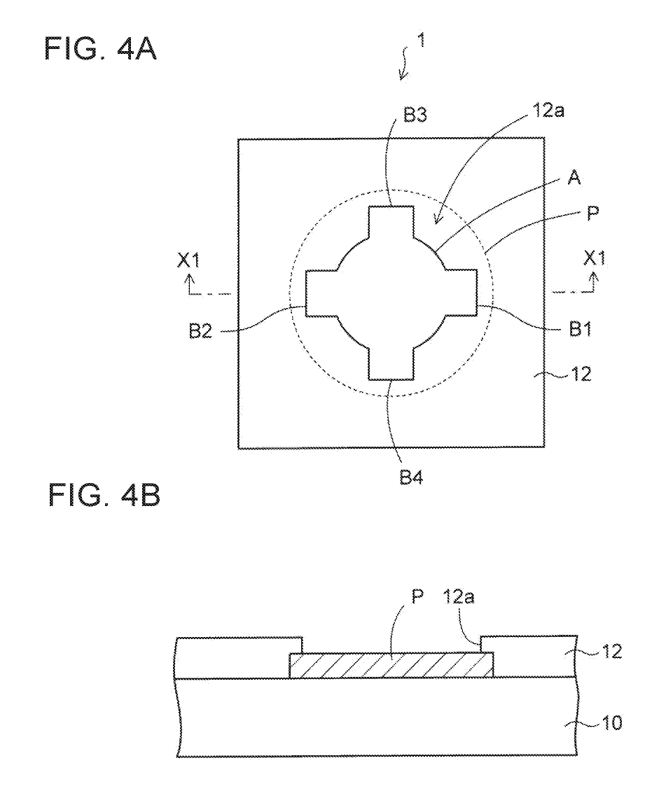

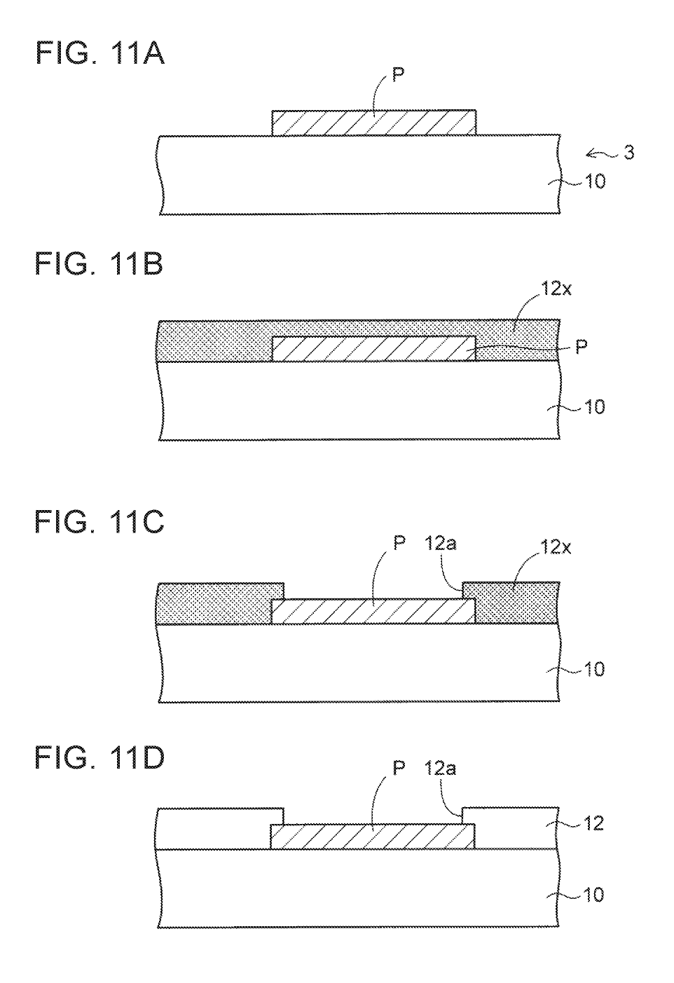

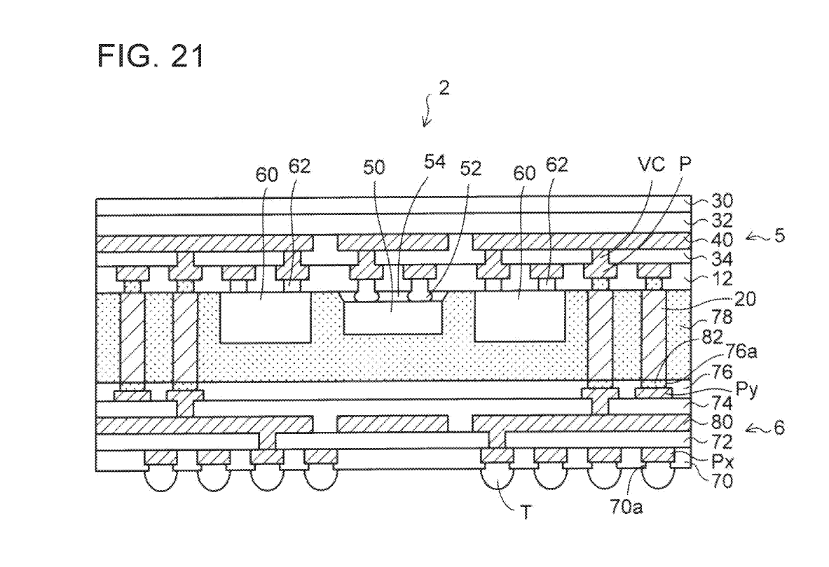

FIGS. 4A to 11D are views for explaining the wiring board according to the embodiment. FIGS. 11A to 20 are views for explaining a method for manufacturing the electronic device according to the embodiment. FIG. 21 is a view showing the electronic device according to the embodiment.

FIGS. 4A and 4B partially show a structure around a connection pad of the wiring board according to the embodiment. FIG. 4B is a sectional view taken along a line XI-XI of FIG. 4A.

As shown in FIGS. 4A and 4B, connection pads P are formed on an insulating layer 10 in the wiring board 1 according to the embodiment.

In addition, a solder resist layer 12 is formed on the insulating layer 10. The solder resist layer 12 covers the connection pads P. At the same time, the solder resist layer 12 is provided with opening portions 12a partially exposing the connection pads P. The opening portions 12a of the solder resist layer 12 are disposed at central portions on the connection pads P. Outer circumferential portions of the connection pads P are covered with the solder resist layer 12.

The solder resist layer 12 is an example of an insulating layer that is formed as an outermost protective layer of the wiring board 1. The solder resist layer 12 is formed out of a photosensitive insulating resin.

In addition, the insulating layer 10 is an interlayer insulating resin layer of an epoxy resin etc. disposed between an upper wiring layer and a lower wiring layer. In addition, the connection pads P are formed out of a wiring material of copper etc. The connection pads P are connected to an internal multilayer wiring layer (not shown) through via conductors (not shown) formed in the insulating layer 10.

Such connection pads P may be arrayed like islands or may be disposed to be connected to one ends or inner parts of lead-out wires.

As shown in FIG. 4A, each of the opening portions 12a of the solder resist layer 12 disposed on the corresponding connection pad P is formed from a main opening portion A and four protrusive opening portions B1 to B4 in plan view. The four protrusive opening portions B1 to B4 protrude outward from an outer circumference of the main opening portion A. The opening portion 12a of the solder resist layer 12 is formed so that the main opening portion A communicates with the four protrusive opening portions B1 to B4.

In the example of FIG. 4A, the main opening portion A is formed into a circle. Each of the protrusive opening portions B1 to B4 is formed into a rectangle. The protrusive opening portions B1 to B4 communicate with the main opening portion A and protrude outward from the outer circumference of the main opening portion A.

As shown in FIG. 4A, a pair of the protrusive opening portions B1 and B2 are disposed to protrude outward respectively from laterally opposite portions of the outer circumference of the main opening portion A. In addition, a pair of the protrusive opening portions B3 and B4 are disposed to protrude outward respectively from longitudinally opposite portions of the outer circumference of the main opening portion A.

An extension direction of the pair of the protrusive opening portions B1 and B2 that are opposed to each other in the lateral direction (an example of a first direction) and an extension direction of the pair of the protrusive opening portions B3 and B4 that are opposed to each other in the longitudinal direction (an example of a second direction) intersect perpendicularly. Incidentally, the lateral direction and the longitudinal direction may not have to intersect perpendicularly to each other.

Thus, in the example of FIG. 4A, the four protrusive opening portions B1 to B4 are disposed at the outer circumference of the main opening portion A such that they form cross shape with the main opening portion A as the center. The cross shape formed by the four protrusive opening portions B1 to B4 may be inclined to a right side or a left side. It will go well as long as the protrusive opening portions B1 to B4 are disposed at four equally divided positions of the outer circumference of the main opening portion A.

The protrusive opening portions B1 to B4 disposed on the outer circumference of the main opening portion A are formed so that when a metal pin is connected to the connection pad P inside the opening portion 12a of the solder resist layer 12, the metal pin can be prevented from being connected with an inclination even if the metal pin is displaced.

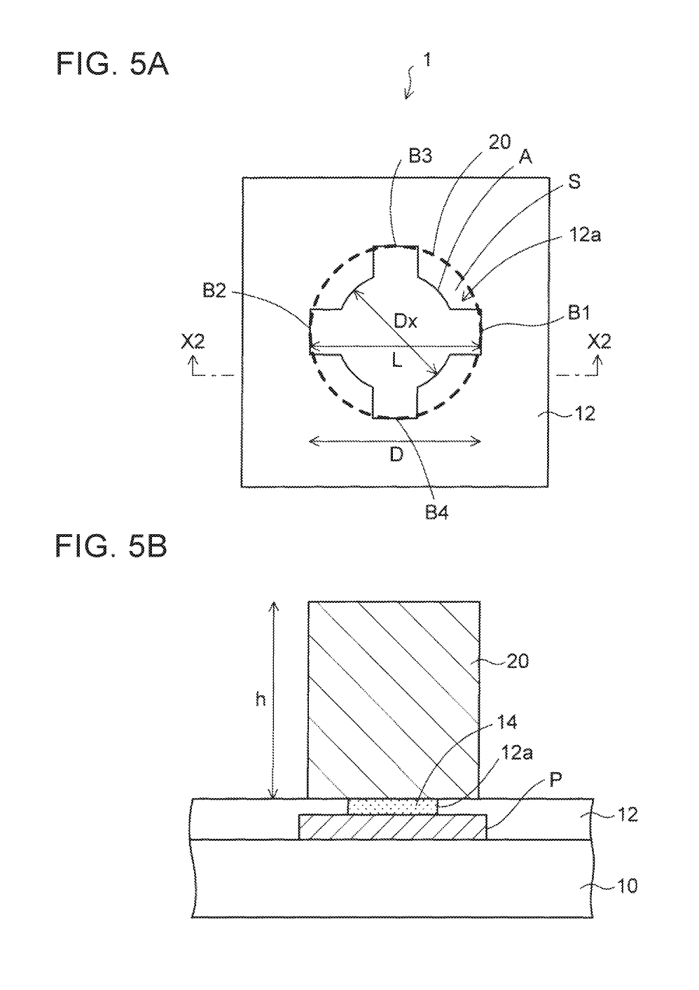

FIGS. 5A and 5B show a case where the metal pin 20 is disposed in alignment with the opening portion 12a of the solder resist layer 12 of FIGS. 4A and 4B. FIG. 5B is a sectional view taken along a line X2-X2 of FIG. 5A. In FIG. 5A, the metal pin 20 is indicated by a thick broken line.

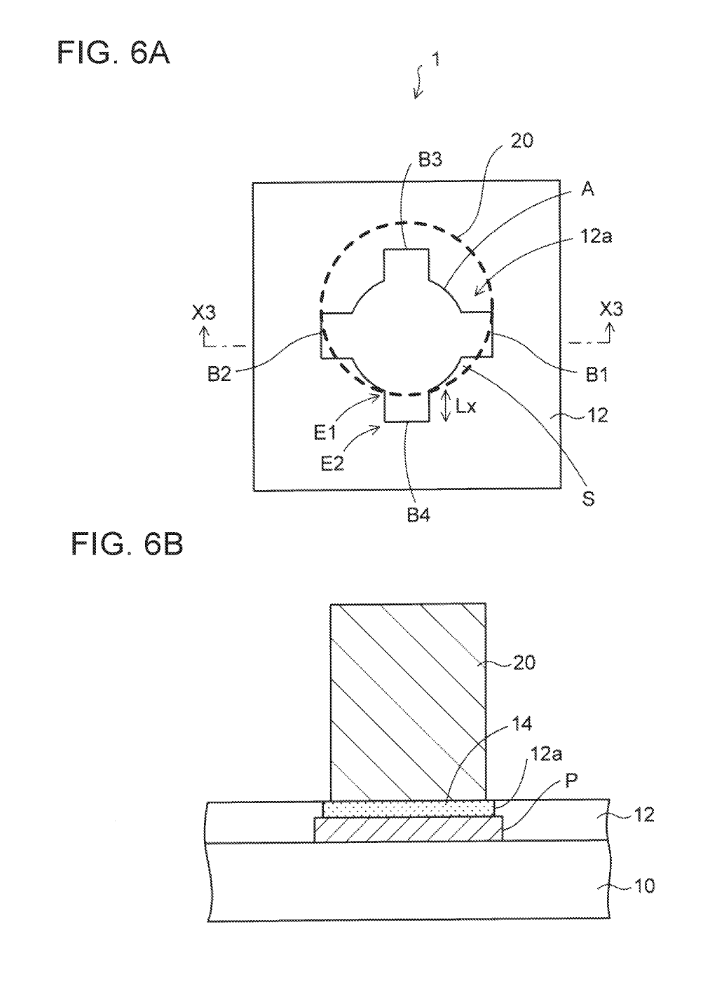

From FIG. 5A, the connection pad P of FIG. 4A has been omitted. The same thing is also applied to FIGS. 6A, 7A and 8A that will be described later.

A length L between one end and the other end of the pair of the opposed protrusive opening portions B1 and B2 (or B3 and B4) of the opening portion 12a of the solder resist layer 12 is set to be the same as a diameter D of the metal pin 20.

In the embodiment, as shown in FIG. 5B, the metal pin 20 is disposed on the solder resist layer 12. The metal pin 20 is connected to the connection pad P through a solder 14. The solder 14 is provided in the opening portion 12a of the solder resist layer 12.

The solder 14 is an example of a metal bonding material. In addition to the solder 14, an electrically conductive paste such as a silver paste may be used. An outer circumferential portion of a lower end surface of the metal pin 20 abuts against an upper surface of the solder resist layer 12. The metal pin 20 is a circularly columnar metal component made of copper etc. An upper end surface and the lower end surface of the metal pin 20 are disposed in parallel with each other and formed as flat surfaces respectively.

The sectional view of FIG. 5B is a sectional view of a lower side region (X2-X2) than the pair of the protrusive opening portions B1 and B2 of FIG. 5A.

Here, the four protrusive opening portions B1 to B4 are disposed around the main opening portion A of the solder resist layer 12, as shown in FIG. 5A. Thus, four upper surface portions S of the solder resist layer 12 are sectioned equally around the main opening portion A.

In a case where the metal pin 20 is disposed in alignment with the opening portion 12a of the solder resist layer 12, as shown in FIGS. 5A and 5B, the outer circumference of the lower end surface of the metal pin 20 is disposed to abut against the equally divided positions of the four upper surface portions S of the solder resist layer 12 around the opening portion 12a. Portions of the outer circumference of the lower end surface of the metal pin 20 are disposed on front ends of the four protrusive opening portions B1 to B4.

Thus, the outer circumference of the lower end surface of the metal pin 20 is disposed on the upper surface portions S of the solder resist layer 12 around the main opening portion A in a yell-balanced manner. Accordingly, the metal pin 20 is connected to the connection pad P through the solder 14 without any inclination

A diameter Dx of the main opening portion A of the opening portion 12a of the solder resist layer 12 is set at 60% to 40% as large as the diameter D of the lower end surface of the metal pin 20. When, for example, the diameter D of the lower end surface of the metal pin 20 is 0.25 mm, the diameter Dx of the main opening portion A of the solder resist layer 12 is set at 0.15 mm to 0.1 mm. In addition, a height h (FIG. 5B) of the metal pin 20 is, for example, 0.45 mm.

In addition, respective areas of the main opening portion A and the protrusive opening portions B1 to B4 are adjusted so that a total area of the opening portion 12a of the solder resist layer 12 is about 60% to 80% as large as an area of the lower end surface of the metal pin 20.

Thus, a connection area using the solder is substantially the same as that in a case where the opening portion of the solder resist layer is disposed in a circular shape. Accordingly, connection strength or reliability of electric connection can be secured even when the protrusive opening portions B1 to B4 are provided.

FIGS. 6A and 6B show a case where the metal pin 20 is disposed to be displaced upward from the opening portion 12a of the solder resist layer 12 of FIGS. 4A and 4B. FIG. 6B is a sectional view taken along a line X3-X3 of FIG. 6A. In FIG. 6A, the metal pin 20 is indicated by a thick broken line.

As shown in FIG. 6A, a length Lx between a base end E1 and a terminal end E2 of each of the protrusive opening portions B1 to B4 connected to the main opening portion A is set to be longer than a maximum displacement amount between the metal pin 20 and the opening portion 12a of the solder resist layer 12.

The maximum displacement amount of the metal pin 20 is a total displacement amount of a displacement amount with which the opening portion 12a of the solder resist layer 12 is formed and a displacement amount with which the metal pin 20 is disposed by means of a pin inserting jig.

Therefore, even when the metal pin 20 is displaced upward from the opening portion 12a of the solder resist layer 12, as shown in FIGS. 6A and 6B, the outer circumference of the lower end surface of the metal pin 20 can be disposed on the protrusive opening portion B4 on the lower side without falling into the main opening portion A.

Thus, the outer circumference of the lower end surface of the metal pin 20 is disposed on the four upper surface portions S of the solder resist layer 12 around the main opening portion A. Accordingly, the metal pin 20 is connected to the connection pin P through the solder 14 without any inclination.

Incidentally, assume that the outer circumference of the lower end surface of the metal pin 20 is disposed to fall into the main opening portion A when the metal pin 20 is displaced. In this case, the metal pin 20 is connected with an inclination even in the embodiment.

To solve this problem, the configuration is made such that, even when the metal pin 20 is displaced at the maximum, the outer circumference of the lower end surface of the metal pin 20 is located outside each of the positions of the base ends E (FIG. 6A) of the protrusive opening portions B1 to B4.

Thus, even when the metal pin 20 is displaced at the maximum, the metal pin 20 can be prevented from being disposed with an inclination. The base ends E of the protrusive opening portions B1 to B4 are portions where the protrusive opening portions B1 to B4 are connected to the outer circumference of the main opening portion A.

Thus, in the wiring board 1 according to the embodiment, the outer circumference of the lower end surface of the metal pin 20 is located outside the position of the outer circumference of the main opening portion A.

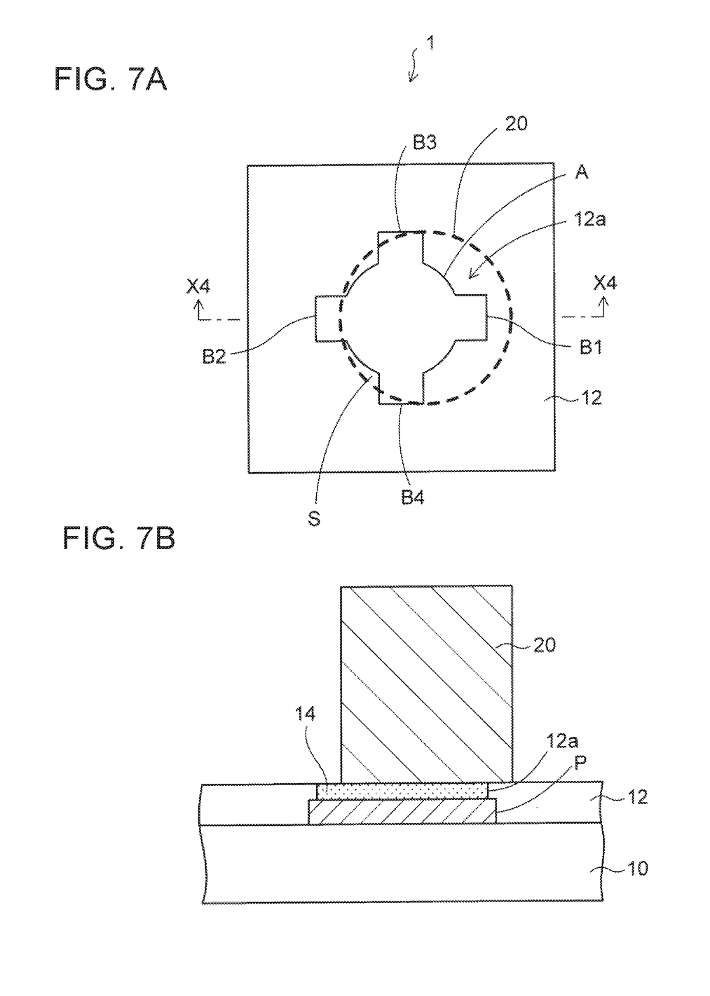

FIGS. 7A and 7B show a case where the metal pin 20 is disposed to be displaced rightward from the opening portion 12a of the solder resist layer 12 of FIGS. 4A and 4B. FIG. 7B is a sectional view taken along a line X4-X4 of FIG. 6A. In FIG. 7A, the metal pin 20 is indicated by a thick broken line.

Even when the metal pin 20 is displaced rightward from the opening portion 12a of the solder resist layer 12 as shown in FIGS. 7A and 7B, the outer circumference of the lower end surface of the metal pin 20 is disposed on the protrusive opening portion B2 on the left side without falling into the main opening portion A.

Thus, the outer circumference of the lower end surface of the metal pin 20 is disposed on the four upper surface portions S of the solder resist layer 12 around the main opening portion A. Accordingly, the metal pin 20 is connected to the connection pad P through the solder 14 without any inclination.

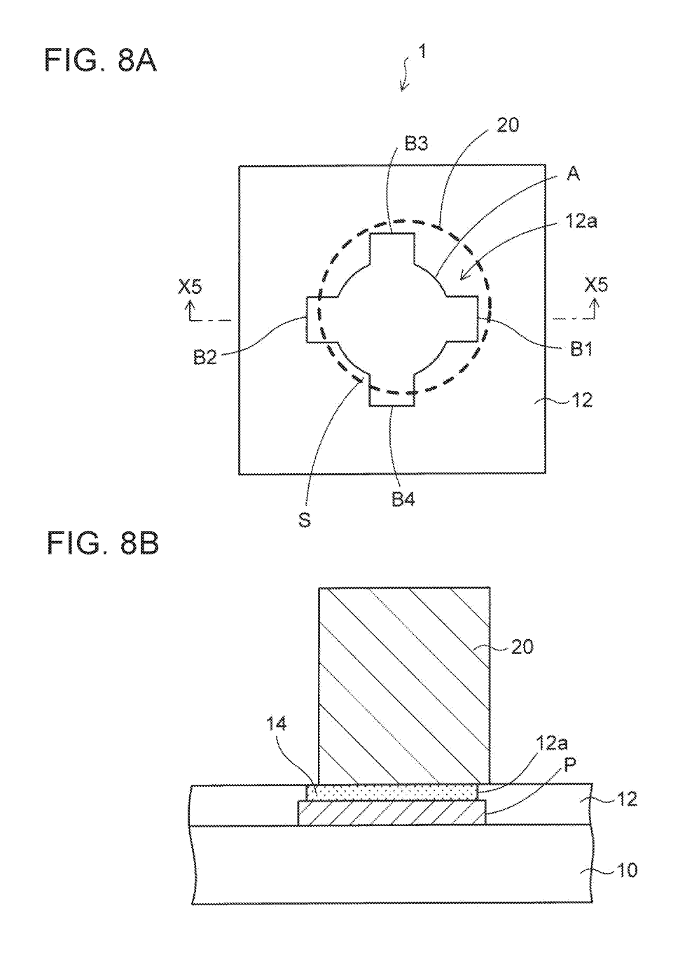

FIGS. 8A and 8B show a case where the metal pin 20 is disposed to be displaced obliquely toward an upper right side from the opening portion 12a of the solder resist layer 12 of FIGS. 4A and 4B. FIG. 8B is a sectional view taken along a line X5-X5 of FIG. 8A. In FIG. 8A, the metal pin 20 is indicated by a thick broken line.

Even when the metal pin 20 is displaced obliquely toward the upper right side from the opening portion 12a of the solder resist layer 12, as shown in FIGS. 8A and 8B, the outer circumference of the lower end surface of the metal pin 20 is disposed on the protrusive opening portions B2 and B4 on the left side and the lower side without falling into the main opening portion A.

Thus, the outer circumference of the lower end surface of the metal pin 20 is disposed on the four upper surface portions S of the solder resist layer 12 around the main opening portion A. Accordingly, the metal pin 20 is connected to the connection pin P through the solder 14 without any inclination.

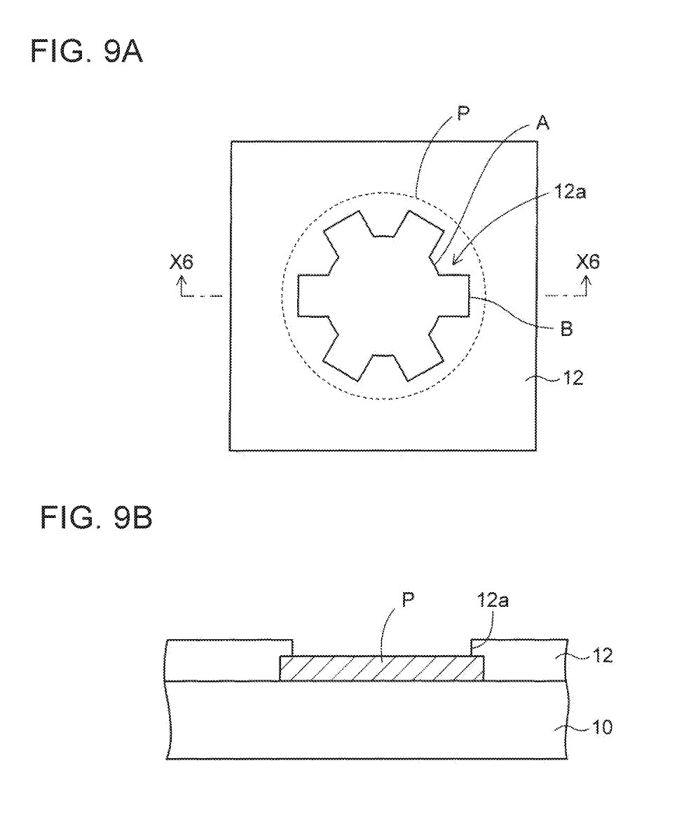

Next, modifications of the shape of the opening portion 12a of the solder resist layer 12 of the wiring board 1 according to the embodiment will be described. FIGS. 9A and 9B show a first modification of the opening portion of the solder resist layer. FIG. 9B is a sectional view taken along a line X6-X6 of FIG. 9A.

As shown in FIGS. 9A and 9B, the number of protrusive opening portions B disposed on the outer circumference of the main opening portion A in the aforementioned FIG. 4A may be increased. In the example of FIG. 9A, six protrusive opening portions B are formed. However, the number of the protrusive opening portions B can be set desirably.

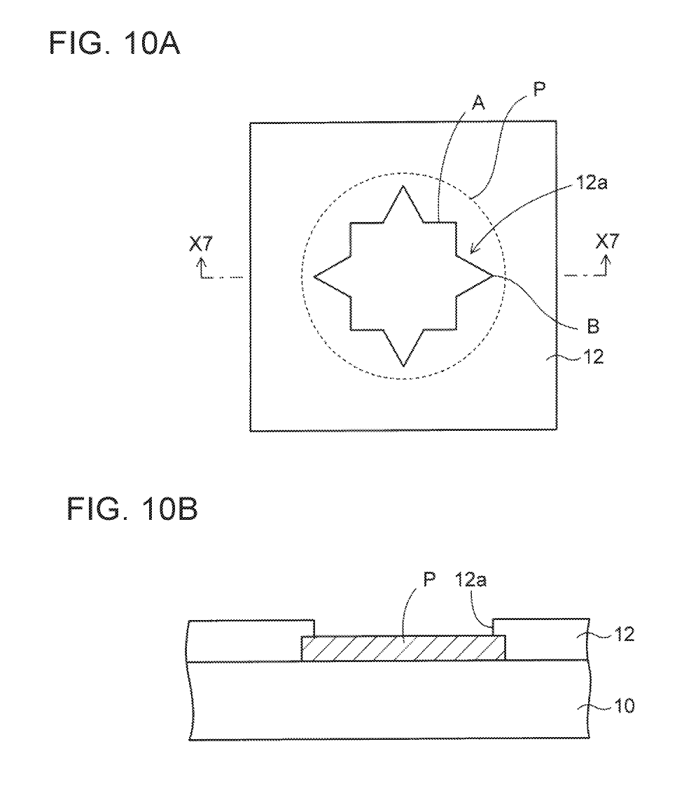

In addition, FIGS. 10A and 10b show a second modification of the opening portion of the solder resist layer. FIG. 10B is a sectional view taken along a line X7-X7 of FIG. 10A.

As shown in FIGS. 10A and 10B, the main opening portion A is shaped like a rectangle. A triangular protrusive opening portion B may be disposed on each of four outer circumferential sides of the main opening portion A.

Other than the circle or the rectangle, the shape of the main opening portion A may be a hexagon, an octagon or an ellipse etc. In addition, the shape of each of the protrusive opening portions B1 to B4 may be an ellipse etc. other than the rectangle and the triangle. Further, it will go well as long as the number of the protrusive opening portions disposed on the outer circumference of the main opening portion A is plural. The number of the protrusive opening portions can he set desirably in consideration of the displacement directions of the metal pin.

Assume that a shape shown in FIG. 9A, a shape shown in FIG. 10A, or the like, is used as the shape of the opening portion 12a of the solder resist layer 12. Even when the metal pin 20 is displaced in this case, the metal pin 20 can be prevented from being connected with an inclination based on the same principle as or a similar principle to the structure of FIG. 4A.

As illustrated in the aforementioned embodiment, the wiring board is provided with the connection pads, the insulating layer (solder resist layer 12) and the metal pins. The insulating layer is provided with the opening portions on the connection pads. The metal pins are connected to the connection pads. Each of the opening portions of the insulating layer is formed from the main opening portion, and the plurality of protrusive opening portions that protrude outward from the outer circumference of the main opening portion.

Next, a method for manufacturing the wiring board according to the embodiment will be described. First, as shown in FIG. 11A, a substrate 3 provided with an insulating layer 10 and connection pads P formed thereon is prepared. Next, as shown in FIG. 11B, a negative type photosensitive resin layer 12x is applied on the insulating layer 10 and the connection pads P.

Successively, as shown in FIG. 11C, a photomask (not shown) for obtaining the shape of the opening portions 12a of the solder resist layer 12 of the aforementioned FIG. 4A is prepared. After being exposed to light through the photomask, the photosensitive resin layer 12x is developed. Thus, the opening portions 12a are formed in the photosensitive resin layer 12x.

In the negative type photosensitive resin layer 12x, portions exposed to the light are crosslinked to be left, and unexposed portions to the light are removed by a developing solution to thereby form the opening portions 12a. Further, the photosensitive resin layer 12x where the opening portions 12a have been formed is cured by heat treatment.

Thus, the opening portions 12a of the solder resist layer 12 of the aforementioned FIG. 4A are obtained, as shown in FIG. 11D. The solder resist layer 12 is an example of an insulating layer. Various insulating materials may be patterned to thereby form the opening portions.

Incidentally, even when a positive type photosensitive resin layer is used in place of the negative type photosensitive resin layer 12x, a solder resist layer provided with the same opening portions or similar opening portions can be formed. In the positive type photosensitive resin layer, exposed portions to light are removed by a developing solution and unexposed portions to the light are left.

Then, metal pins are connected to the connection pads P inside the opening portions 12a of the solder resist layer 12 through solders. A connection method of the metal pins will be described in an undermentioned method for manufacturing an electronic device.

Next, a method for manufacturing a stacked type electronic device using the wiring board 1 according to the embodiment as shown in the aforementioned FIGS. 4A and 4B will be described.

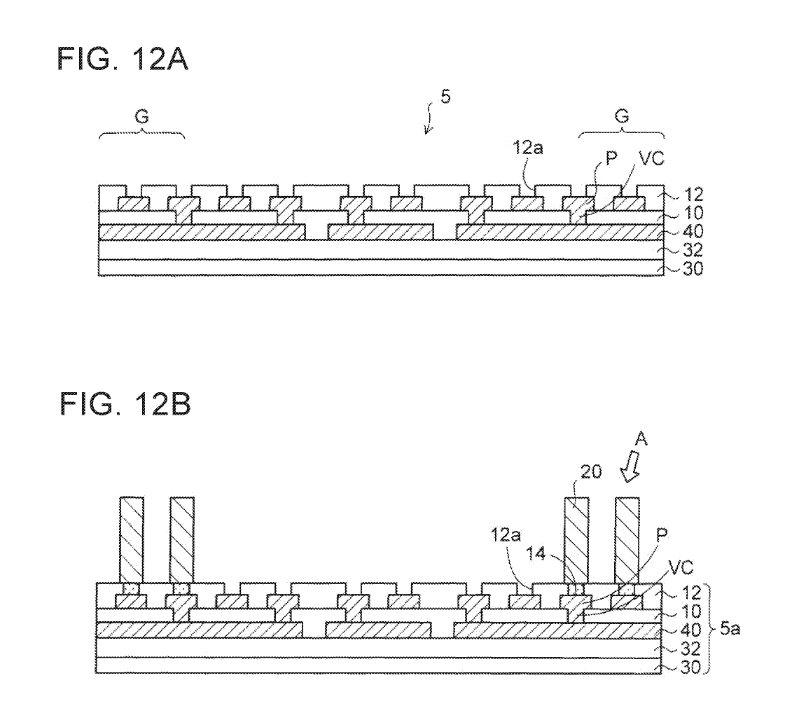

In FIG. 12A, an entire state of the wiring board 1 in the aforementioned FIGS. 4A and 4B is shown as a first wiring board 5. As shown in FIG. 12A, an insulating layer 32 is formed on a protective insulating layer 30 disposed as a lowermost layer in the first wiring board 5. A wiring layer 40 is formed on the insulating layer 32.

Further, an insulating layer 10 is formed on the insulating layer 32 and the wiring layer 40. In addition, connection pads P are formed on the insulating layer 10. The connection pads P are connected to the wiring layer 40 through via conductors VC formed in the insulating layer 10.

In addition, a solder resist layer 12 is formed on the insulating layer 10 and the connection pads P. Opening portions 12a of the solder resist layer 12 are disposed on the connection pads P. The opening portions 12a of the solder resist layer 12 at regions indicated by G in FIG. 12A have the same shape as that in the aforementioned FIG. 4A. Connection pins are connected to the connection pads P at the regions indicated by G.

As shown in FIG. 12B, lower end surfaces of the metal pins 20 are connected to the connection pads P through solders 14.

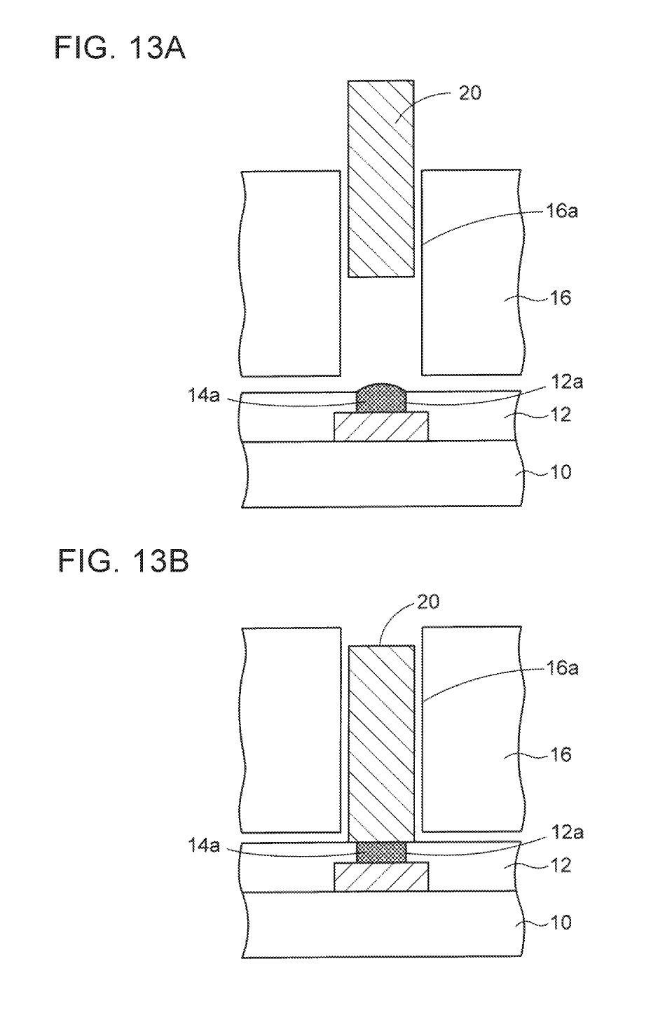

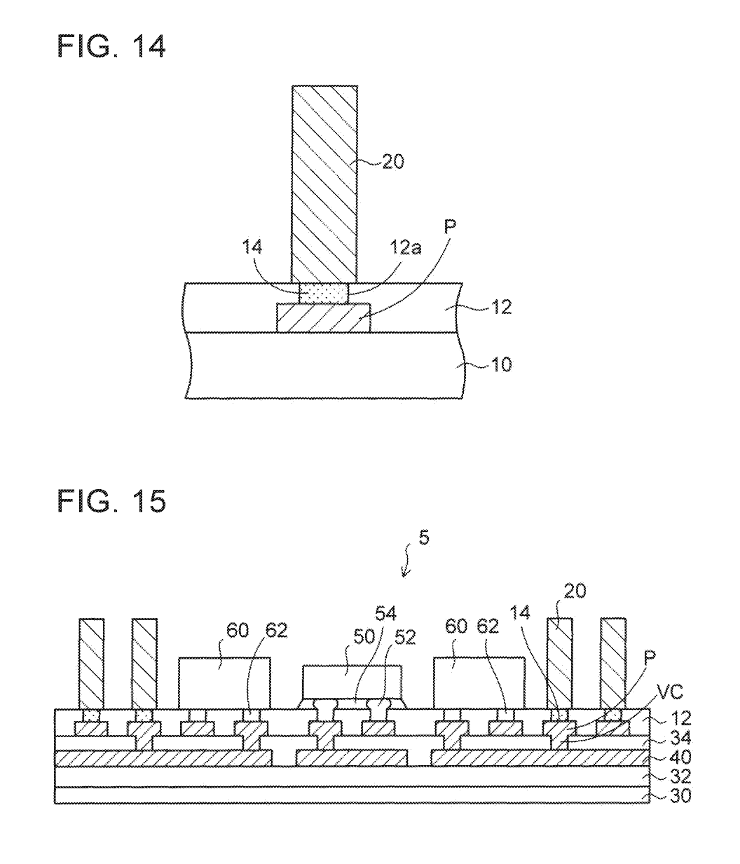

FIGS. 13A and 13B and FIG. 14 show the connection method of the metal pins 20. As shown in FIG. 13A, first, a solder paste 14a containing flux is applied on the connection pad P inside each of the opening portions 12a of the solder resist layer 12 of the first wiring board 5.

Further, a pin inserting jig 16 is prepared. A plurality of insertion holes 16a are provided in the pin inserting jig 16. The insertion holes 16a of the pin inserting jig 16 are disposed correspondingly to the connection pads P to which the metal pins of the first wiring board 5 are connected.

Successively, an alignment mark (not shown) formed in the solder resist layer 12 is recognized as an image. Thus, the insertion holes 16a of the pin inserting jig 16 are aligned with the opening portions 12a of the solder resist layer 12 of the first wiring board 5. The metal pins 20 are inserted through the insertion holes 16a of the pin inserting jig 16 from above.

Thus, as shown in FIG. 13B, the metal pins 20 drop onto the solder pastes 14a on the connection pads P due to their own weights so as to be temporarily bonded to the solder pastes 14a. The outer circumference portions of lower end surfaces of the metal pins 20 abut against an upper surface of the solder resist layer 12.

As described above, each of the opening portions 12a of the solder resist layer 12 is provided with protrusive opening portions B1 to B4. Therefore, even when any of the metal pins 20 is misaligned, the outer circumference of the lower end surface of the metal pin 20 abuts against the upper surface of the solder resist layer 12 in a well-balanced manner. Accordingly, it is possible to prevent the metal pin 20 from being disposed with an inclination.

A clearance between an inner wall of each of the insertion holes 16a of the pin inserting jig 16 and an outer surface of each of the metal pins 20 is small. Accordingly, the metal pin 20 is provided substantially vertically to be connected to the connection pad

Then, the pin inserting jig 16 is removed from the first wiring board 5 to which each of the metal pins 20 has been temporarily bonded, as shown in FIG. 14.

Further, the solder paste 14a is subjected to reflow heating. Thus, the metal pin 20 is connected to the connection pad P through the solder 14 disposed in the opening portion 12a of the solder resist layer 12.

When, for example, a lead-free solder such as a tin (Sn)—silver (Ag)—copper (Cu) solder is used as the solder paste 14a, the reflow heating is performed at a temperature of 220° C. to 270° C. Then, defluxing is performed.

The volume of the solder paste 14a of FIG. 13A is adjusted so that when the solder paste 14a is subjected to reflow heating, the flux can flow to the outside from the solder paste 14a to entirely fill the opening portion 12a of the solder resist layer 12 with the solder 14.

On this occasion, the upper surface of the solder resist layer 12 is poor in wettability of the solder, and the outer circumferential portion of the lower end surface of the metal pin 20 abuts against the upper surface of the solder resist layer 12 surrounding the opening portion 12a. Therefore, when the solder 14 is melted by the reflow heating, the solder 14 does not flow between the lower end surface of the metal pin 20 and the upper surface of the solder resist layer 12.

Thus, in a state in which the outer circumferential portion of the lower end surface of the metal pin 20 abuts against the upper surface of the solder resist layer 12, the metal pin 20 is reliably connected to the connection pad P through the solder 14 without any inclination.

Next, a semiconductor chip 50 and a capacitor element 60 are prepared, as shown in FIG. 15. Bump electrodes 52 of the semiconductor chip 50 are flip-chip connected to connection pads P of a component mounting region of the first wiring board 5. Further, a gap between a lower side of the semiconductor chip 50 and the upper surface of the solder resist layer 12 is filled with an underfill resin 54.

In addition, connection terminals 62 of the capacitor element 60 are connected to connection pads P lateral to the semiconductor chip 50.

Each of the semiconductor chip 50 and the capacitor element 60 are an example of an electronic component. Various electronic components may be mounted.

In the aforementioned manner, the first wiring board 5 in which the metal pins 20 are connected and the semiconductor chip 50 and the capacitor element 60 are mounted can be obtained. The first wiring board 5 includes the metal pins 20, the semiconductor chip 50 and the capacitor element 60.

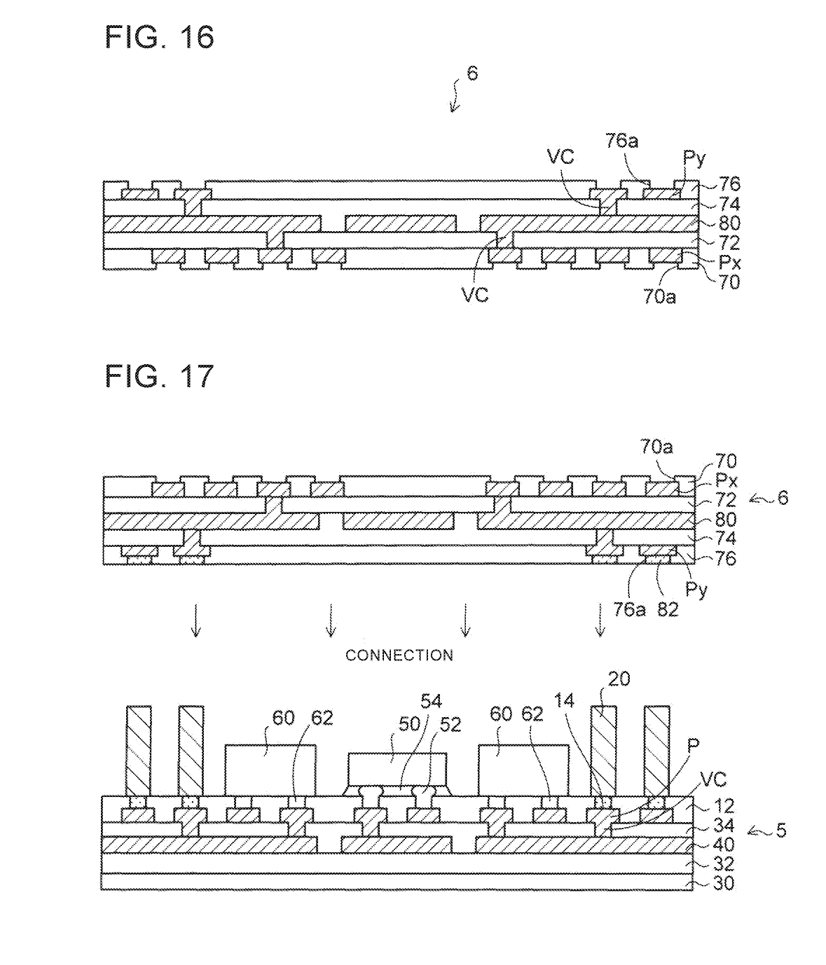

Next, as shown in FIG. 16, a second wiring board 6 is prepared. In the second wiring board 6, connection pads Px are formed on a lower surface of an insulating layer 72, and a wiring layer 80 is formed on an upper surface of the insulating layer 72. The connection pads Px are connected to the wiring layer 80 through via conductors VC formed in the insulating layer 72.

A solder resist layer 70 in which opening portions 70a are disposed on the connection pads Px is formed on the bottom of the insulating layer 72.

In addition, an insulating layer 74 is formed on the insulating layer 72 and the wiring layer 80. Further, connection pads Py are formed on the insulating layer 74. The connection pads Py are connected to the wiring layer 80 through via conductors VC formed in the insulating layer 74.

A solder resist layer 76 in which opening portions 76a are disposed on the connection pads Py is formed on the insulating layer 74.

The connection pads Py serve as electrodes connected to the metal pins 20 of the aforementioned first wiring board 5. The connection pads Py are disposed correspondingly to the arrays of the metal pins 20. In addition, the connection pads Px on an opposite side to the connection pads Py serve as external connection electrodes.

Next, after solders 82 are applied onto the connection pads Py of the second wiring board 6 of FIG. 16, the second wiring board 6 is inverted vertically and the connection pads Py of the second wiring board 6 are disposed in alignment with the metal pins 20 of the first wiring board 5, as shown in FIG. 17.

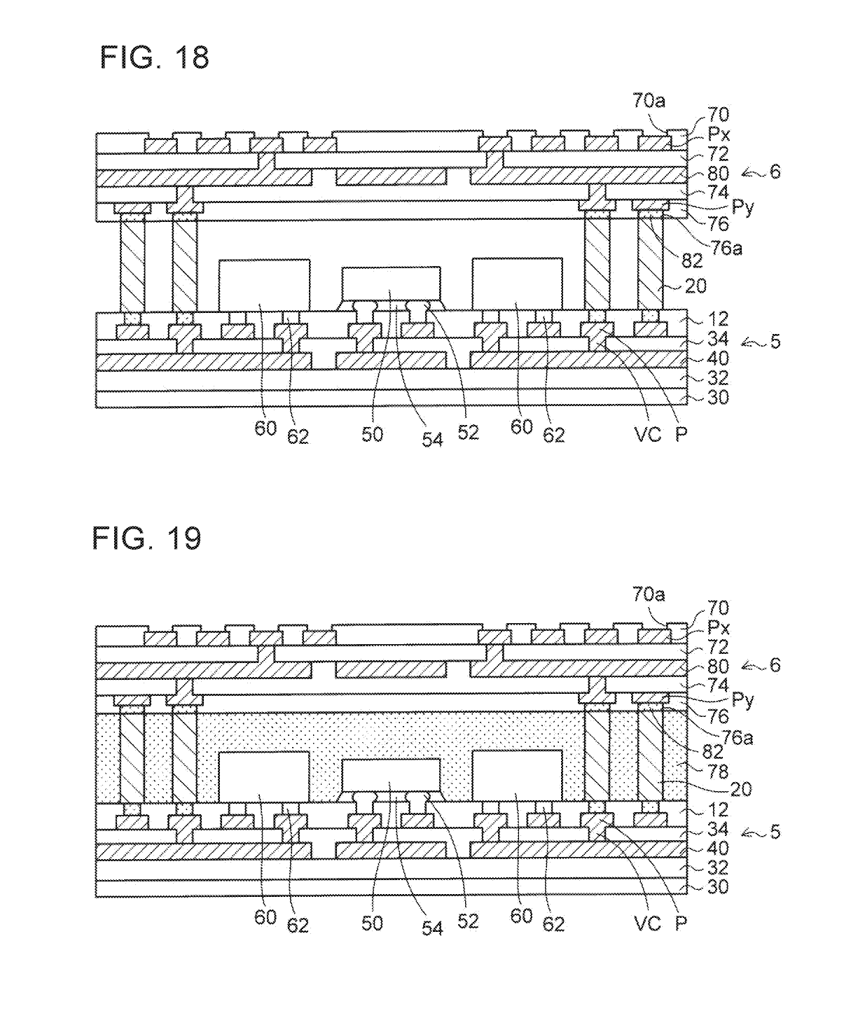

Further, reflow heating is performed so that the connection pads Py of the second wiring board 6 are connected to upper end surfaces of the metal pins 20 of the first wiring board 5 through the solders 82, as shown in FIG. 18. On this occasion, the metal pins 20 of the first wiring board 5 are disposed vertically without any inclination, as described above.

Therefore, it is possible to solve a problem that the metal pins 20 of the first wiring board 5 may be displaced from the connection pads Py of the second wiring board 6 or may not reach the connection pads Py. Accordingly, the connection pads Py of the second wiring board 6 are reliably connected to the metal pins 20 of the first wiring board 5.

Successively, a gap between the first wiring board 5 and the second wiring board 6 is filled with a sealing resin 78, as shown in FIG. 19. Thus, the semiconductor chip 50, the capacitor element 60 and the metal pins 20 are sealed with the sealing resin 78.

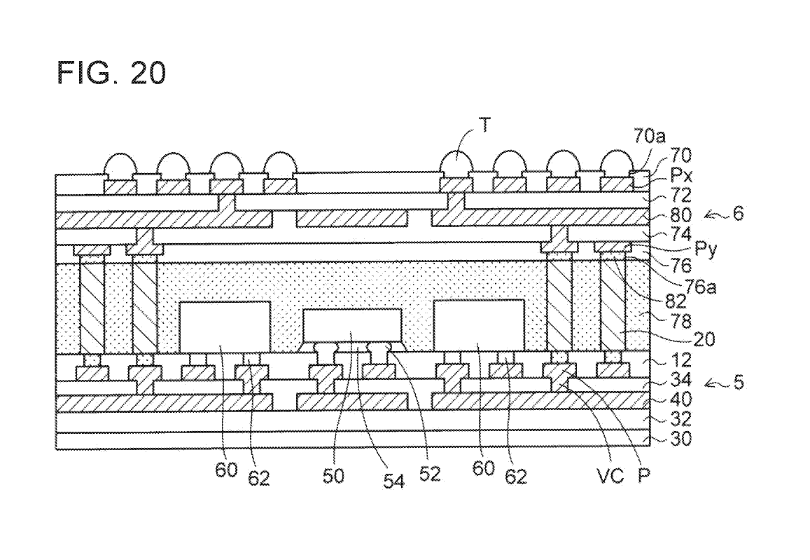

Further, for example, solder balls are mounted on the connection pads Px of the second wiring board 6 to form external connection terminals T, as shown in FIG. 20.

In the aforementioned manner, an electronic device 2 according to the embodiment is obtained, as shown in FIG. 21. In FIG. 21, a structure body of FIG. 20 is inverted vertically. When a large-sized board in which a large number of product regions have been defined to obtain multiple boards therefrom is used as the first wiring board 5 and the second wiring board 6, the large-sized board extending from the first wiring board 5 and the second wiring board 6 is cut so that an individual electronic device 2 can be obtained from each of the product regions.

In the electronic device 2 according to the embodiment, as shown in FIG. 1, the connection pads Py of the aforementioned second wiring board 6 shown in FIG. 16 are connected to the front end surfaces of the metal pins 20 of the aforementioned first wiring board 5 shown in FIGS. 12A to 15 through the solders 82.

In addition, the gap between the first wiring board 5 and the second wiring board 6 is filled with the sealing resin 78. The semiconductor chip 50, the capacitor element 60, and the metal pins 20 mounted on the first wiring board 5 are sealed and encapsulated with the sealing resin 78. Further, the external connection terminals T are provided on the connection pads Px on the lower surface side of the second wiring board 6. The external connection terminals T of the electronic device 2 are connected to connection electrodes of a mounting board such as a motherboard.

The external connection terminals T of the electronic device 2 are connected to the metal pins 20 of the first wiring board 5 through the connection pads Px, the wiring layer 80 and the connection pads Py of the second wiring board 6. In addition, the metal pins 20 of the first wiring board 5 are connected to the semiconductor chip 50 and the capacitor element 60 through the connection pads P and the wiring layer 40.

In the electronic device 2 according to the embodiment, the metal pins 20 of the first wiring board 5 can be prevented from being connected with an inclination, as described above. Therefore, the metal pins 20 of the first wiring board 5 and the connection pads Py of the second wiring board 6 can be reliably connected with each other respectively so that a manufacturing yield can be improved.

In addition, since the metal pins 20 of the first wiring board 5 are prevented from being inclined, a pitch between adjacent ones of the arrays of the metal pins 20 can be made narrower to support higher density and higher performance of the electronic device.

In the aforementioned embodiment, the opening portions 12a of the solder resist layer in FIG. 4A are formed on the connection pads P of the first wiring board 5, and the metal pins 20 are connected to the connection pads P of the first wiring board 5.

Alternatively, the opening portions 12a of the solder resist layer 12 in FIG. 4A may be disposed on the connection pads Py of the second wiring board 6 in FIG. 16, and the metal pins 20 may be also connected to the connection pads Py of the second wiring board 6.

In addition, the opening portions 12a of the solder resist layer 12 in FIG. 4A may be disposed on both the connection pads P of the first wiring board 5 and the connection pads Py of the second wiring board 6.

In addition, the first wiring board 5 is mounted with the electronic components in FIG. 21. However, the first wiring board 5 may be a wiring hoard not mounted with any electronic component. As another form, the electronic components may he mounted on a surface of the protective insulating layer 30 side of the first wiring board 5 or the electronic components may be embedded into the first wiring board 5.

In addition, the second wiring board 6 is not mounted with any electronic component. However, the second wiring board 6 may be a wiring board mounted with the electronic components.

The electronic components may be mounted on one of the first wiring board 5 and the second wiring board 6, or the electronic components may be mounted on both the first wiring board 5 and the second wiring board 6.

Alternatively, both the first wiring board 5 and the second wiring board 6 may be wiring boards or interposers etc. not mounted with any electronic component.

As described above, the exemplary embodiment and the modification are described in detail. However, the present invention is not limited to the above-described embodiment and the modification, and various modifications and replacements are applied to the above-described embodiment and the modifications without departing from the scope of claims.

Various aspects of the subject matter described herein are set out non-exhaustively in the following numbered clauses:

(1) A method of manufacturing a wiring board, the method comprising:
preparing a substrate provided with a connection pad;
forming an insulating layer on the substrate so as to cover the connection pad, wherein the insulating layer has an opening portion exposing a portion of the connection pad; and
connecting a metal pin to the connection pad through a metal bonding material provided in the opening portion,
wherein the opening portion comprises a main opening portion, and a plurality of protrusive opening portions that communicate with the main opening portion and that protrude outward from an outer circumference of the main opening portion, and
an outer circumference of a lower end surface of the metal pin, which is opposed to the insulating layer, is located outside the outer circumference of the main opening portion.

(2) The method according to clause (1), wherein the metal pin is connected to the connection pad in a state in which the outer circumference of the lower end surface of the metal pin abuts against an upper surface of the insulating layer.

What is claimed is:

1. A wiring board comprising:
a connection pad;
an insulating layer that covers the connection pad and has an opening portion exposing a portion of the connection pad; and
a metal pin that is disposed on the insulating layer and that is connected to the connection pad through a metal bonding material provided in the opening portion,
wherein the opening portion comprises a main opening portion, and a plurality of protrusive opening portions that communicate with the main opening portion and that protrude outward from an outer circumference of the main opening portion, and
an outer circumference of a lower end surface of the metal pin, which is opposed to the insulating layer, is located outside the outer circumference of the main opening portion.

2. The wiring board according to claim 1, wherein
the plurality of protruding opening portions comprise:
a first protrusive opening portion that protrudes outward from the outer circumference of the main opening portion in a first direction;
a second protrusive opening portion that protrudes outward from the outer circumference of the main opening portion in the first direction, wherein the second protrusive opening portion is opposed to the first protrusive opening portion;
a third protrusive opening portion that protrudes outward from the outer circumference of the main opening portion in a second direction different from the first direction; and
a fourth protrusive opening portion that protrudes outward from the outer circumference of the main opening portion in the second direction, wherein the fourth protrusive opening portion is opposed to the third protrusive opening portion.

3. The wiring board according to claim 2, wherein the first direction and the second direction intersect perpendicularly to each other.

4. The wiring board according to claim 1, wherein the outer circumference of the lower end surface of the metal pin abuts against an upper surface of the insulating layer.

5. The wiring board according to claim 1, wherein the main opening portion is shaped like a circle, and each of the protrusive opening portions is shaped like a rectangle.

6. The wiring board according to claim 1, wherein the plurality of protrusive opening portions are disposed to be point-symmetrical with respect to a center of the main opening portion.

7. The wiring board according to claim 1, wherein a diameter of the main opening portion is 40% to 60% as large as a diameter of the lower end surface of the metal pin.

8. The wiring board according to claim 1, wherein an area of the opening portion is 60% to 80% as large as an area of the lower end surface of the metal pin.

9. An electronic device comprising:
a first wiling board; and
a second wiring board that is electrically connected to the first wiring board,
wherein the first wiring board comprises:
a first connection pad;
an insulating layer that covers the first connection pad, and has an opening portion exposing a portion of the first connection pad; and
a metal pin that is disposed on the insulating layer and that is connected to the first connection pad through a metal bonding material provided in the opening portion,
wherein the opening portion comprises a main opening portion, and a plurality of protrusive opening portions that communicate with the main opening portion and that protrude outward from an outer circumference of the main opening portion,
an outer circumference of a lower end surface of the metal pin, which is opposed to the insulating layer, is located outside the outer circumference of the main opening portion, and
wherein the second wiring substrate comprises a second connection pad that is connected to an upper end surface of the metal pin, which is opposite to the lower end surface.

10. The electronic device according to claim 9, further comprising:
an electronic component mounted on at least one of the first wiring board and the second wiring board; and
a sealing resin provided between the first wiring board and the second wiring board to encapsulate the electronic component and the metal pin.
